(19) United States
(12) Patent Application Publication
(10) Pub. No.: US 2014/0339688 A1
(43) Pub. Date: Nov. 20, 2014

(54) TECHNIQUES FOR THE CANCELLATION OF CHIP SCALE PACKAGING PARASITIC LOSSES

(71) Applicant: CAVENDISH KINETICS, INC., San Jose, CA (US)

(72) Inventors: Roberto GADDI, 's-Hertogenbosch (NL); Robertus Petrus VAN KAMPEN, S-Hertogenbosch (NL); Dennis J. YOST, Los Gatos, CA (US); Paul Albert CASTILLOU, San Jose, CA (US); Atul Prakash SHINGAL, Fremont, CA (US)

(73) Assignee: CAVENDISH KINETICS, INC., San Jose, CA (US)

(21) Appl. No.: 14/278,901

(22) Filed: May 15, 2014

Related U.S. Application Data
(60) Provisional application No. 61/823,695, filed on May 15, 2013.

(51) Int. Cl. B81B 7/00

(52) U.S. Cl. CPC B81B 7/0064; B81B 7/0006; B81B 2207/096
USPC 257/659; 257/737

(57) ABSTRACT

The present invention generally relates to techniques and structures that cancel or mitigate RF coupling from the RF circuit to the silicon die. To cancel or mitigate the RF coupling, a conductive coating may be formed over the RF-MEMS device. The conductive coating may be coupled to the die. Alternatively, the conductive coating may be coupled to the die through the RF-MEMS by having a through silicon via. Another manner for cancelling or mitigating RF coupling is to have no conductive traces located on the front side of the PCB.

### CROSS-REFERENCE TO RELATED APPLICATIONS

This application claims benefit of U.S. Provisional Patent Application Ser. No. 61/823,695, filed May 15, 2013, which is herein incorporated by reference.

### BACKGROUND OF THE INVENTION

1. Field of the Invention

Embodiments of the present invention generally relate radio frequency chip scale packaging (CSP) components based on monolithically integrated complementary metal oxide semiconductor (CMOS) and low loss passive components and switches.

2. Description of the Related Art

As the complexity of modern RF front-ends increases, new technologies are being developed which enable new functionalities inside all the key circuit blocks of the RF transmit and receive chain. Such circuit blocks are, among others, filters, up-converters, down-converters, duplexers, power splitters/combiners, phase shifters, TX/RX switches and antennas.

A competitive advantage of such new technologies is to offer a CMOS digital/power interface monolithically integrated with the RF component. As an example, an RF-MEMS based very low loss variable capacitor technology can be integrated on the same silicon die with CMOS digital interface and voltage shifters, providing a low size chips scale package components that can be directly assembled in the application circuit.

Wafer level chip-scale packaging (WLCSP) is for this reason a packaging technique that becomes more and more appealing for RF front-end application circuits which impose small size and low cost as well as high RF performance. In WLCSP, the bare chip obtained from the silicon wafer at the back-end of the manufacturing process is equipped with contact bumps or pillars and can therefore directly be assembled on the application printed circuit board (PCB). The die is flip-chipped beside other surface mount components and the mechanical and electrical contact is established using standard surface mount assembly techniques such as solder reflow.

This new integration scheme, WLCSP, applied to RF-microwave circuits implies that the metal traces running on the PCB are in close proximity with the CSP silicon die. This generates electric field and magnetic field coupling phenomena which transfer some small fractions of the RF power directly in the bulk of the silicon die. Without implementing further mitigation and cancellation techniques of such coupling effects, there will be power losses since the bulk silicon is a low conductivity material.

Therefore, there is a need in the art for cancellation or mitigation techniques for CSP.

### SUMMARY OF THE INVENTION

The present invention generally relates to techniques and structures that cancel or mitigate RF coupling from the RF circuit to the silicon die. To cancel or mitigate the RF coupling, a conductive coating may be formed over the RF-MEMS device. The conductive coating may be coupled to the die. Alternatively, the conductive coating may be coupled to the die through the RF-MEMS by having a through silicon via. Another manner for cancelling or mitigating RF coupling is to have no conductive traces located on the front side of the PCB.

In one embodiment, a CSP RF-MEMS device comprises a printed circuit board having a plurality of conductive traces disposed on a side thereof; a solder mask layer disposed over at least one conductive trace; a die having sidewalls, a backside, and a frontside; pads coupled to the frontside of the die; conductive bumps coupled to the pads and the conductive traces; and a conductive shield disposed over the sidewalls and backside of the die.

In another embodiment, a CSP RF-MEMS device comprises a printed circuit board having one or more first conductive traces disposed on a side thereof, one or more second conductive traces disposed on the same side as the one or more first conductive traces, and one or more third conductive traces embedded within the printed circuit board, the one or more second conductive traces are coupled to the one or more third conductive traces through conductive filled vias; a solder mask layer disposed over one or more first conductive traces; a die having sidewalls, a backside, and a frontside; pads coupled to the frontside of the die; conductive bumps coupled to the pads and the one or more second conductive traces.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross-sectional illustration of a CSP of a MEMS device.

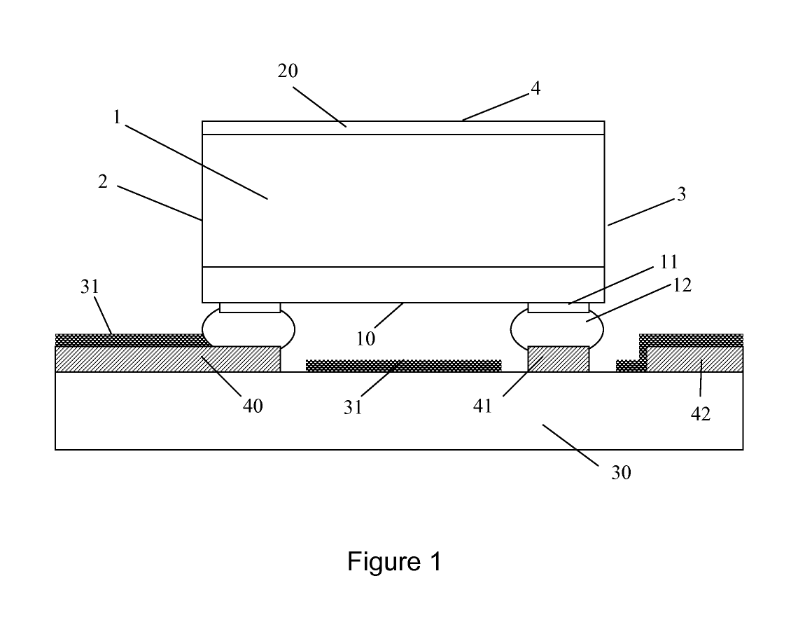

FIG. 2 is a schematic cross-sectional illustration of CSP for a MEMS device according to one embodiment.

FIG. 3 is a schematic cross-sectional illustration of CSP for a MEMS device according to another embodiment.

FIG. 4 is a schematic cross-sectional illustration of CSP for a MEMS device according to another embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present invention generally relates to techniques and structures that cancel or mitigate RF coupling from the RF circuit to the silicon die. To cancel or mitigate the RF coupling, a conductive coating may be formed over the RF-MEMS device. The conductive coating may be coupled to the die. Alternatively, the conductive coating may be coupled to the die through the RF-MEMS by having a through silicon via. Another manner for cancelling or mitigating RF coupling is to have no conductive traces located on the front side of the PCB.

A standard CSP component is made of a bulk silicon substrate (1), of thickness in the 100's of micrometer range. The die has a front side (10) and a back side (4). The back side is typically coated (20) and marked. The front side integrates the active CMOS circuitry, the back-end metallization embedded in the passivation layers. The passivation has openings and pads (11) and on top of such pads conductive bumps or pillars are manufactured (12).

During CSP packaging the die is flipped and mounted on a PCB (30), so that the front side will face the top side of the PCB. On the top side of the PCB there are metal/conductive traces (40, 41, 42) covered typically with a solder mask layer (31). During assembly, the solder bumps or pillars of the CSP die are going to make electrical and mechanical contact with the PCB metal in locations where the solder mask has openings.

Electric or magnetic coupling will occur between PCB metal traces running in close proximity of the CSP die. For example, conductor (40) can electrically couple to the die side-wall (2) and back-side (4). Conductor (42), assumed to run perpendicular to the drawing plane, can also electrically couple to the die side-wall (3) and back-side (4), but also magnetically couple directly to the die bulk silicon (1).

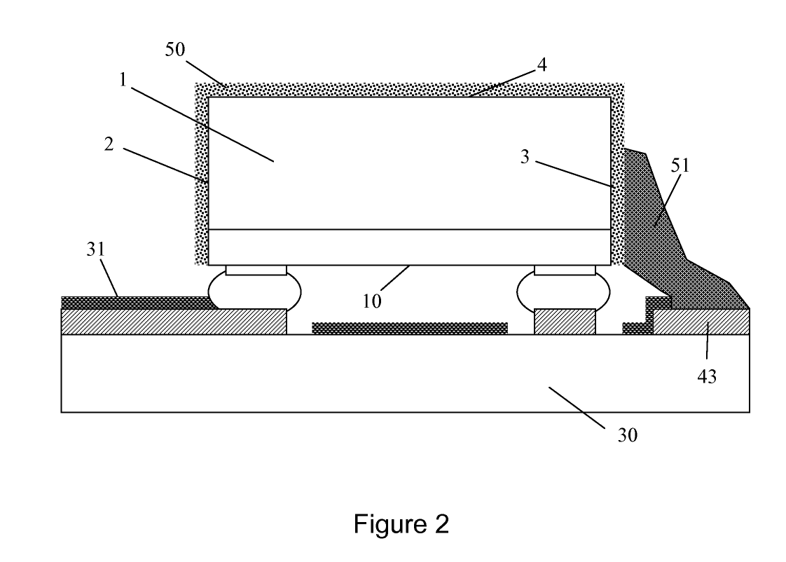

In one embodiment, the die's side walls (2-3) and back-side (4) are coated with a conductive material (50) (FIG. 2). This material can be for example conductive epoxy (sprayed or painted) metal (sputtered or evaporated). This can already provide a shield cancelling magnetic coupling to the silicon substrate.

As a further embodiment, the circuit PCB can be designed so that a metal trace connected to the common ground electric potential is placed close to the CSP die (43) and a solder mask opening is generated next to one side-wall. A conductive connection can be created (51) which will put the conductive shield (50) at electrical ground potential. This implements an electric shielding cancelling all losses due to electric coupling from PCB metal traces to the CSP die side-walls and back-side.

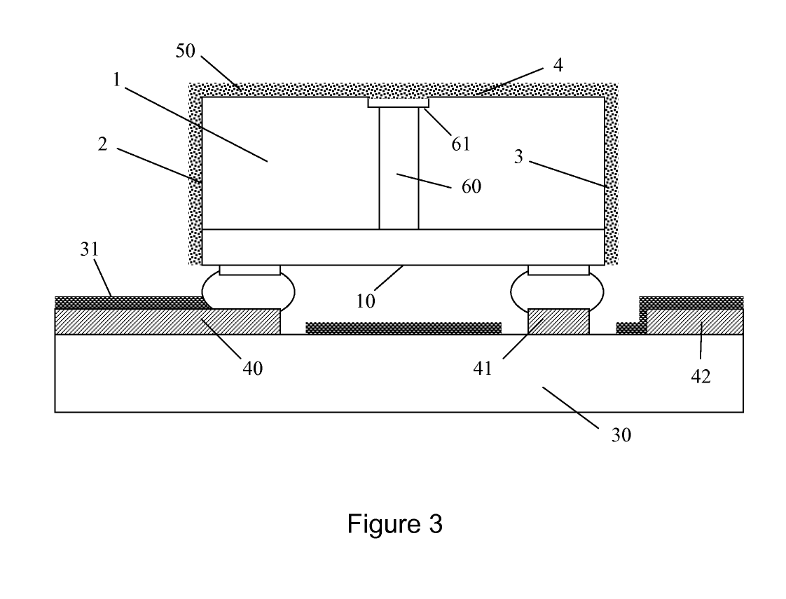

In a different implementation, an electrical conductor (60) (FIG. 3) is implemented between front-side and back-side of the die. This can be manufactured for example with through-silicon vias (TSV) techniques. An electrical conductive pad (61) is also manufactured at the back-side of the die. This whole conductive path is connected to the common ground potential of the device. When applying the conductive coating (50), electrical connection is made between the conductive coating (50) and the pad (61), putting the whole conductive shield at the common ground potential. This implements an electric shielding cancelling all losses due to electric coupling from PCB metal traces to the CSP die side-walls and back-side.

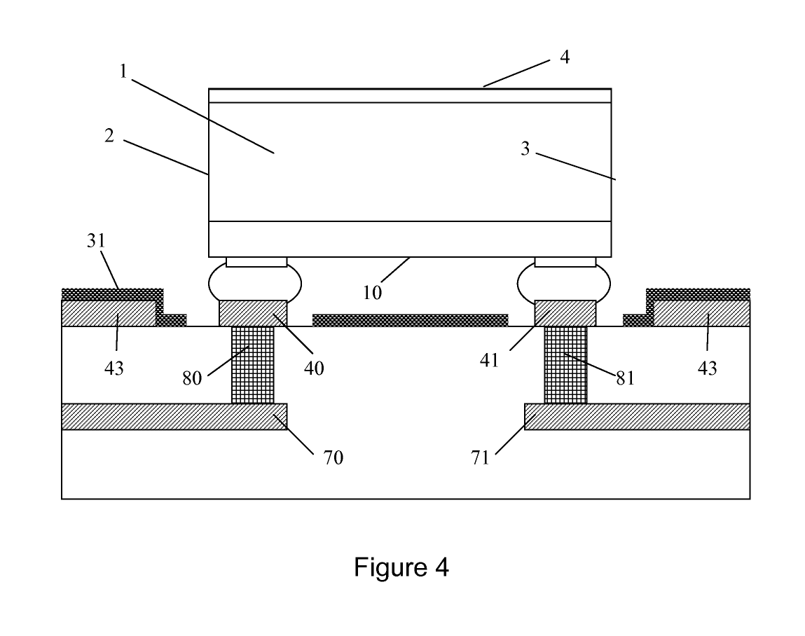

In a different embodiment, the PCB circuit is designed such that no conductive traces are located on the front side of the PCB apart from common ground connected traces/planes (43) (FIG. 4). All other conductive traces are embedded inside the PCB substrate (70, 71), using techniques such as “pre-impregnated” composite fibers (prepreg) bonding sheets used to combine multiple laminate cores. If the circuit design does not allow implementing this across the whole PCB, it is sufficient to limit this buried signal implementation to the proximity of the CSP die, within a distance of 10× the die thickness.

The electrical connections to the die will be implemented using blind micro-vias (80, 81) under the pads (40, 41). This will cancel all magnetic and electric coupling between the CSP die and the circuit signals, avoiding extra power loss. No extra processing is required in the CSP die back-end fabrication.

The cancellation techniques here described have the advantage of enabling the use of low-cost CMOS based CSP components inside high performance RF circuit blocks without any power loss penalties due to electric or magnetic coupling. This will enable low size, low cost and high performance RF front-ends.

While the foregoing is directed to embodiments of the present invention, other and further embodiments of the invention may be devised without departing from the basic scope thereof, and the scope thereof is determined by the claims that follow.

1. A CSP RF-MEMS device, comprising:
a printed circuit board having a plurality of conductive traces disposed on a side thereof;
a solder mask layer disposed over at least one conductive trace;
a die having sidewalls, a backside, and a frontside;
pads coupled to the frontside of the die;
conductive bumps coupled to the pads and the conductive traces; and
a conductive shield disposed over the sidewalls and backside of the die.

2. The CSP RF-MEMS device of claim 1, wherein the conductive shield is coupled to at least one trace of the plurality of conductive traces.

3. The CSP RF-MEMS device of claim 1, wherein die has a filled through silicon via extending from the backside to the frontside and wherein the conductive shield is coupled to the filled through silicon via.

4. A CSP RF-MEMS device, comprising:
a printed circuit board having one or more first conductive traces disposed on a side thereof, one or more second conductive traces disposed on the same side as the one or more first conductive traces, and one or more third conductive traces embedded within the printed circuit board, the one or more second conductive traces are coupled to the one or more third conductive traces through conductive filled vias;
a solder mask layer disposed over one or more first conductive traces;
a die having sidewalls, a backside, and a frontside;
pads coupled to the frontside of the die; and
conductive bumps coupled to the pads and the one or more second conductive traces.
